(19) United States
(12) Patent Application Publication
(10) Pub. No.: US 2025/0216420 A1
(43) Pub. Date: Jul. 3, 2025

(54) INTEGRATED CIRCUIT AND POWER CIRCUIT WITH CURRENT SENSE CIRCUIT

(71) Applicant: Chengdu Monolithic Power Systems Co., Ltd., Chengdu (CN)

(72) Inventor: Yong Zhou, Chengdu (CN)

(21) Appl. No.: 19/007,157

(22) Filed: Dec. 31, 2024

(30) Foreign Application Priority Data
Jan. 3, 2024 (CN) 202410009293.3

(51) Int. Cl. G01R 1/20; G01R 19/00

(52) U.S. Cl. CPC G01R 1/203; G01R 19/00

(57) ABSTRACT

A current sense circuit for sensing a current flowing through a device is provide. The current sense circuit includes a first sensing terminal, a second sensing terminal, a sensing output terminal, and a current source. The first sensing terminal is configured to be coupled to a first terminal of a current sense resistor coupled in series with the device. The second sensing terminal is configured to be coupled to a second terminal of the current sense resistor. The sensing output terminal is configured to provide a sensing signal indicative of the current flowing through the current sense resistor. The current source is coupled to the second sensing terminal of the current sense circuit.

### PRIORITY CLAIM AND CROSS-REFERENCE

This application claims priority to Chinese Patent Application No. 202410009293.3, filed on Jan. 3, 2024, which is hereby incorporated by reference in its entirety.

### BACKGROUND

### Field of Invention

The present application relates to power circuits, and more particularly but not exclusively to current sense circuits of integrated circuits and power integrated circuits.

### Description of Related Art

Current sense circuits have been widely used in power circuits. A conventional way is to use a current sense resistor connected in series with a device to obtain the current flowing through the device. In other words, the voltage across the two terminals of the current sense resistor indicates the current flowing through the resistor and the device (I=V/R).

A high-side current sense circuit is typically used with a current sense resistor connected between a power supply and a load. Specifically, the current sense resistor has a first terminal coupled to a first input terminal of an operational amplifier through a first drop element and a second terminal coupled to a second input terminal of the operational amplifier through a second drop element. An output terminal of said operational amplifier is coupled to a control terminal of a voltage-controlled current source, a terminal of the voltage-controlled current source is coupled to the first input terminal of the operational amplifier, and another terminal of the voltage-controlled current source is coupled to a reference ground through a third resistance. By detecting the voltage across the third resistor as the output voltage, a current flowing through the current sense resistor may be obtained through the output voltage.

There is a linear relationship between the output voltage of the high-side current sense circuit and the current flowing through the current sense resistor with a zero-crossing point, thereby achieves the current sense function. However, when the current flowing through the current sense resistor is negative, the circuit could not provide a negative voltage and can only provide a zero voltage. Therefore, it is desirable to provide a current sensing circuit with wide-range for both a positive current and a negative current flowing through the same current path

### SUMMARY

In one embodiment of the present disclosure, a current sense circuit for sensing a current flowing through a device is provide. The current sense circuit includes a first sensing terminal, a second sensing terminal, a sensing output terminal, and a current source. The first sensing terminal is configured to be coupled to a first terminal of a current sense resistor coupled in series with the device. The second sensing terminal is configured to be coupled to a second terminal of the current sense resistor. The sensing output terminal is configured to provide a sensing signal indicative of the current flowing through the current sense resistor. The current source is coupled to the second sensing terminal of the current sense circuit.

In one embodiment of the present disclosure, a current sense circuit for sensing a current flowing through a device is provided. The current sense circuit includes a first sensing terminal, a second sensing terminal, and sensing output terminal. The first sensing terminal is coupled to a first terminal of a current sense resistor coupled in series with the device. The second sensing terminal is coupled to a second terminal of the current sense resistor. The sensing output terminal is configured to provide a voltage signal indicative of the current flowing through the current sense resistor. When the voltage signal is equal to a first value, the current flowing through the current sense resistor is zero; when the voltage signal is greater than the first value, the current flows in a first direction from the first terminal of the current sense resistor to the second terminal of the current sense resistor; and when the voltage signal is less than the first value, the current flows a second direction from the second terminal of the current sense resistor to the first terminal of the current sense resistor.

In one embodiment of the present disclosure, a power integrated circuit includes a current sense circuit configured to sense a current flowing through a device. The current sense circuit is configured operate under a normal operation mode or a calibration mode. Under the normal operation mode, the current sense circuit is configured to sense the current flowing through the device and provide a voltage signal indicative of the current. Under the calibration mode, the device is not connected to the current sense circuit.

### BRIEF DESCRIPTION OF THE DRAWINGS

The disclosure can be more fully understood by reading the following detailed description of the embodiment, with reference made to the accompanying drawings as follows.

FIG. 1 is a schematic circuit diagram of a current sense circuit according to a n embodiment of the present disclosure.

FIG. 2 is a schematic diagram of a gain of a current sense circuit according to an embodiment of the present disclosure.

FIG. 3 is a schematic circuit diagram of a current sense circuit according to an embodiment of the present disclosure.

FIG. 4 is a schematic circuit diagram of a current sense circuit according to an embodiment of the present disclosure.

FIGS. 5(a) and 5(b) are schematic circuit diagrams of a current sense circuit under operation modes according to an embodiment of the present disclosure.

FIG. 6 is a schematic circuit diagram of a current sense circuit according to an embodiment of the present disclosure.

FIGS. 7(a) and 7(b) are schematic circuit diagrams of a current sense circuit under operation modes according to an embodiment of the present disclosure.

FIG. 8 is a schematic circuit diagram of a current sense circuit according to an embodiment of the present disclosure.

FIGS. 9(a) and 9(b) are schematic circuit diagrams of a current sense circuit under operation modes according to an embodiment of the present disclosure.

### DETAILED DESCRIPTION

Embodiments of the present invention will be described in detail below. It should be noted that the embodiments described here are only for illustration and are not intended to limit the present invention. In the following description, numerous specific details are set forth in order to provide a thorough understanding of the invention. However, it will be apparent to one of ordinary skill in the art that these specific details need not be employed in order to practice the invention. In other instances, well-known materials or methods have not been described in detail in order to avoid obscuring the present invention.

Throughout this specification, the phrases “in one embodiment,” “in an embodiment,” “in one example,” or “in one implementation” as used includes both combinations and sub-combinations of various features, structures, or characteristic described herein as well as variations and modifications thereof. These phrases used herein do not necessarily refer to the same embodiment, although it may.

Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Furthermore, particular features, structures, or characteristics may be included in an integrated circuit, an electronic circuit, a combinational logic circuit, or other suitable components that provide the described functionality. Furthermore, those of ordinary skill in the art will appreciate that the drawings provided herein are for illustrative purposes and that the drawings are not necessarily drawn to scale. The same reference numbers indicate the same elements. As used herein, the term “and/or” includes any and all combinations of one or more of the associated listed items.

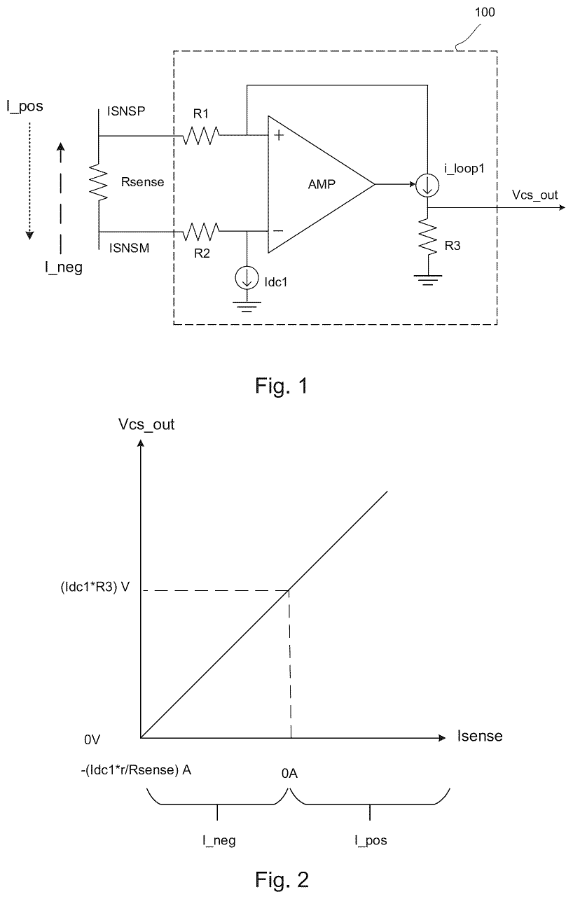

FIG. 1 is a schematic circuit diagram of a current sense circuit 100 according to an embodiment of the present disclosure. The current sense circuit 100 is configured to sense a current flowing through a device. As stated, a current sense resistor Rsense is coupled in series with the device (not shown) to represent the current flowing through the device. As shown in FIG. 1, the current sense resistor Rsense is coupled between the first sensing terminal ISNSP and the second sensing terminal ISNSM. The first sensing terminal ISNSP of the current sense circuit 100 is coupled to a first terminal of the current sense resistor Rsense, and the second sensing terminal ISNSM of the current sense circuit 100 is coupled to a second terminal of the current sense resistor Rsense. The current sense circuit 100 has a current source Idc1 coupled to the second terminal of the current sense resistor Rsense. In some embodiments, the current source Idc1 is a constant current source.

The current sense circuit 100 includes an operational amplifier AMP, having a first input terminal, a second input terminal, and an output terminal. The current sense circuit 100 further includes a first drop element R1 and a second drop element R2. The first drop element R1 coupled between the first sensing terminal ISNSP and the first input terminal of the operational amplifier AMP. The second drop element R2 is coupled between the second sensing terminal ISNSM and the second input terminal of the operational amplifier AMP. The current sense circuit 100 further includes a first current source i_loop1 coupled between the first input terminal of the operational amplifier AMP and a reference ground through a third resistor R3. The first current source i_loop1 is a voltage-controlled current source, and the output terminal of the operational amplifier AMP is coupled to a control terminal of the first current source i_loop1. The current sense circuit 100 further includes a current source Idc1 coupled between a second terminal of the operational amplifier AMP and a reference ground.

It is defined that a current flowing from the first sensing terminal ISNSP to the second sensing terminal ISNSM is in a positive direction and indicated as a positive current I_pos, and a current flowing from the second sensing terminal ISNSM to the first sensing terminal ISNSP is in a negative direction and indicated as a negative current I_neg. In the current sense circuit 100 shown in FIG. 1, the resistance of the first drop element R1 and the resistance of the second drop element R2 are the same (e.g., r). The current sense resistor Rsense is a drop element.

When the output voltage Vcs_out is zero, the current I_loop=0, and the following mathematical relationship is satisfied:

$$Idc {1}^{*} R 2 = {Rsense}^{*} I\_neg . \qquad ( 1 )$$

As a result, the maximum current value in the negative direction (i.e., I_neg) that can be sensed by the current sense circuit 100 is Idc1*r/Rsense. In other words, the sensing range of the negative current of the current sense circuit 100 can be adjusted according to the value of the current source Idc1.

When the current flowing through the current sense resistor Rsense is zero, the following mathematical relationship is satisfied:

$$I\_pos = I\_neg = 0. \qquad ( 2 )$$

Suppose the first drop element R1 and the second drop element R2 have the same resistance, when the current flowing through the current sense resistor Rsense is zero, the following mathematical relationships are satisfied:

$$i\_loop1 = Idc 1 ; and \qquad ( 3 )$$

$$Vcs\_out ( 0 A ) = {i\_loop1}^{*} R 3 = Idc {1}^{*} R 3. \qquad ( 4 )$$

When the current flowing through the current sense resistor Rsense is in a negative direction (i.e., the negative current I_neg), the following mathematical relationships is satisfied:

$$i\_loop1 = ( Idc {1}^{*} r - {I\_neg}^{*} Rsense ) / r ; and \qquad ( 5 )$$

$$Vcs\_out = {i\_loop1}^{*} R 3 = Idc {1}^{*} R 3 - {I\_neg}^{*} {Rsense}^{*} R 3 / r = Vcs\_out ( 0 A ) - {I\_neg}^{*} Gain . \qquad ( 6 )$$

That is, when the current flows through the current sense resistor Rsense in the negative direction as the negative current I_neg, the gain of the current sense circuit could be expressed as: Rsense*R3/r. According to similar derivations, the output voltage Vcs_out when detecting the positive current I_pos could be expressed as:

$$Vcs\_out = Vcs\_out ( 0 A ) + {I\_pos}^{*} Gain . \qquad ( 7 )$$

FIG. 2 shows a schematic diagram of the gain of a current sense circuit 100. For instance, the relationship between the sensing current Isense flowing through the current sense resistor and the output voltage Vcs_out indicating the current flowing through the device is shown. As stated above, when the output voltage Vcs_out is 0V, the value of the negative current I_neg is (Idc1*r/Rsense) according to equation (1), and the sensing current Isense is shown as −(Idc1*r/Rsense). In other words, the current sense circuit 100 is able to detect a negative current of Idc1*r/Rsense. In contrast, the conventional current sense circuit detects zero current flowing through the current sense resistor (i.e., zero current) at a zero output voltage Vcs_out=0V. In some embodiments of the present disclosure, as shown in FIG. 2, when the sensing current I is 0 A, the output voltage Vcs_out is Idc1*R3. When the output voltage Vcs_out is equal to Idc1*R3, the sensing current Isense is zero. When the output voltage Vcs_out is greater than Idc1*R3, the sensing current Isense is a positive current I_pos flowing in a first direction from the first terminal of the current sense resistor to the second terminal of the current sense resistor. When the output voltage Vcs_out is less than the Idc1*R3, the sensing current Isense is a negative current I_neg flowing a second direction from the second terminal of the current sense resistor to the first terminal of the current sense resistor. Therefore, the current sense circuit 100 provides a wide range of current sensing ability, which senses a positive current, and also sense a negative current.

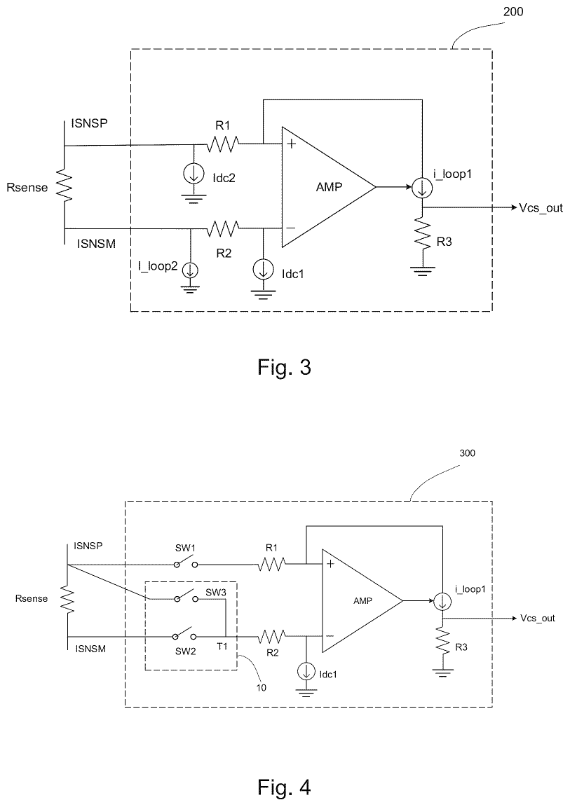

FIG. 3 is a schematic circuit diagram of a current sense circuit 200 according to an embodiment of the present disclosure. Compared with the current sense circuit 100 in FIG. 1, the current sense circuit 200 further includes a third current source Idc2 in series with the first drop element R1. In one embodiment the third current source Idc2 is coupled between the first terminal of the first drop element R1 and the reference ground. The current sense circuit 200 further includes a fourth current source i_loop2 coupled in series with the second drop element R2. In one embodiment, the fourth current source i_loop2 is coupled between the first terminal of the second drop element R2 and the reference ground. The current value of the third current source Idc2 is the same as the current value provided by the current source Idc1. The current value provided by the fourth current source i_loop2 is the same as a current value provided by the voltage-controlled current source i_loop1. One in the art can adopt various means to provide the current source. For example, a current mirror is used for replicating the current source Idc1, and provide the copied current as the third current source Idc2. By adding the third current source Idc2 and the fourth current source i_loop2, the influence of the parasitic resistance (e.g., due to metal wires, indicated as Rwire) is reduced, and therefore the current sensing accuracy is improved. Specifically, the voltage across the first sensing terminal ISNSP and the first terminal of the first drop element R1 is Rwire*(Idc2+I_loop1), the voltage across the second sensing terminal ISNSM and the first terminal of the second drop element R2 is Rwire*(Idc1+I_loop2), and the two voltage should be the same to cancel the deviation such that the two input voltages of the operational amplifier should be the same.

According to the formulas (6) and (7), the output voltage when no current is flowing through the current sense resistor Rsense (i.e., Vcs_out(0 A)) is critical as it determines the output voltage Vcs_out. Furthermore, the output voltage when no current is flowing through the current sense resistor Rsense (i.e., Vcs_out(0 A)) also indicates the cut-off point between the positive current I_pos and the negative current I_neg. However, in practical applications, due to variance and deviation of the device, process and other parameters during manufacturing the circuit and during operating, the current value and voltage of the circuit may not be accurate. For example, the current sense output becomes inaccurate in high temperature, the Vcs_out(0 A) is not accurate at Idc1*R3, the accuracy of the current sense circuit may be affected. Therefore, the present disclosure also proposes a circuit for performing the calibration at any time to solve this problem.

When the current sense circuit of some embodiments of the present disclosure operates under a calibration mode, the current sense is not performed. Specifically, the current sense resistor is not connected to the current sense circuit by disconnecting the circuit structure (e.g., selectively turning off some switches). At this time, the output voltage does not reflect the current information of the sensing device. In some embodiments, under the calibration mode, the first terminal of the first drop element R1 and the first terminal of the second drop element R2 are connected to a node of a same voltage level or different nodes of the same voltage level.

Some embodiments are provided below for illustrating how to realizing the calibration function. The switch circuit (or switch network) 10 shown in FIGS. 4, 6, and 8 allows the current sense circuit to switch between a normal operation mode and a calibration mode. Although the switching circuit 10 is connected as shown in FIGS. 4, 6, and 8, the present disclosure is not limited thereto. It is obvious for ordinary skilled in the art, the switch circuit may include more or less switches, or have different circuit structures coupled between the first sensing terminal and the second sensing terminal of the current sense circuit to realize the calibration function.

FIG. 4 is a schematic circuit diagram of a current sense circuit 300 according to an embodiment of the present disclosure. Compared with the current sense circuit 100 in FIG. 1, the current sense circuit 300 further includes a first switch SW1, a second switch SW2, and a third switch SW3. The first switch SW1 is coupled between the first sensing terminal ISNSP and the first drop element R1. The second switch SW2 is coupled between the second sensing terminal ISNSM and the second drop element R2, the third switch SW3 is coupled between the first sensing terminal ISNSP and the second drop element R2. For example, a first terminal of the second switch SW2 and a first terminal of the third switch SW3 are respectively coupled to the second sensing terminal ISNSM and the first sensing terminal ISNSP, and a second terminal of the second switch SW2 is coupled to a second terminal of the third switch SW3 to form a first common node T1, which is coupled to a first terminal of the second drop element R2. The current sense circuit 300 has plural controllable switches (e.g., three controllable switches shown in FIG. 4), and by controlling the controllable switches, the current sense circuit 300 may be controlled to operate under a normal operation mode or a calibration mode, and the current sense circuit 300 under the calibration mode may have a calibration function.

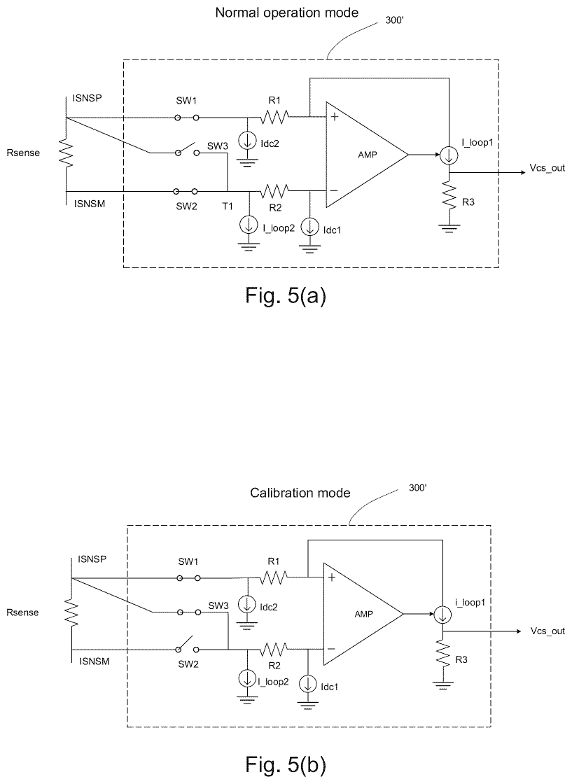

FIGS. 5(a) and 5(b) are schematic circuit diagrams showing the working principle of the calibration mode of a current sense circuit 300′ according to an embodiment of the present disclosure. In some embodiments, the current sense circuit 300′ in FIGS. 5(a) and 5(b) further includes a third current source Idc2 coupled in series with the second terminal of the first switch SW1 and a fourth current source i_loop2 coupled in series with the first common node T1. The current value provided by the third current source Idc2 is the same as a current value provided by the current source Idc1, and a current value provided by the fourth current source i_loop2 is the same as a current value provided by the voltage-controlled current source i_loop1. One in the art can adopt various means to replicate the current source. For example, a current mirror is used for replicating the current source Idc1, and provide the copied current as the third current source Idc2. And, in some examples, a current mirror is used for replicating the voltage-controlled current source i_loop1, and provide the copied current as the fourth current source i_loop2. By adding the third current source Idc2 and the fourth current source i_loop2, the influence of the parasitic resistance (e.g., due to metal wires) on the current sensing accuracy can be effectively reduced.

As shown in FIG. 5(a), under a normal operation mode, the first switch SW1 and the second switch SW2 are turned on, and the third switch SW3 is turned off. When the operating condition changes (e.g., the temperature changes) or when the user considers calibration is needed, control signals are provided to control the three switches to make the current sense circuit 300 operate under a calibration mode. Under the calibration mode, as shown in FIG. 5(b), the first switch SW1 and the third switch SW3 are turned on, and the second switch SW2 is turned off. In other words, the two input terminals of the current sense circuit 300′ (e.g., the two input terminals of the operational amplifier AMP) are coupled to the same terminal (the first sensing terminal ISNSP) to receive the same voltage, and there is no current flowing across the two input terminals of the current sense circuit 300′ (i.e., zero current 0 A). Accordingly, under the calibration mode, the value of the output voltage Vcs_out (i.e., Vcs_out(0 A)) is obtained and recorded. In some embodiments, the value of the output voltage (i.e., Vcs_out(0 A)) is compared with a preset value to obtain the deviation. When the current sense circuit operates under a normal operation mode, the deviation is taken into consideration to compensate the output voltage.

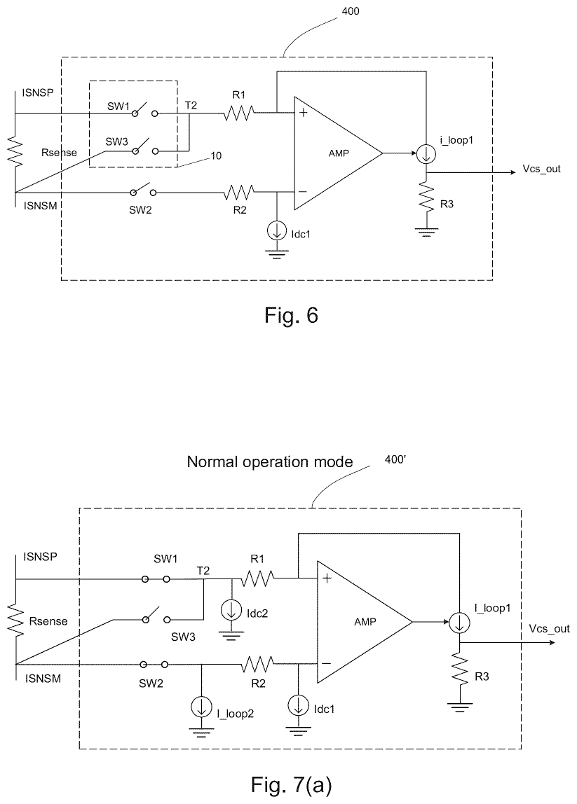

FIG. 6 is a schematic circuit diagram of a current sense circuit 400 according to one embodiment of the present disclosure. Compared with the current sense circuit 100 in FIG. 1, the current sense circuit 400 further includes a first switch SW1, a second switch SW2, and a third switch SW3. The second switch SW2 is coupled between the second sensing terminal ISNSM and the second drop element R2. The first switch SW1 is coupled between the first sensing terminal ISNSP and the first drop element R1. The third switch SW3 is coupled between the second sensing terminal ISNSM and the first drop element R1. For example, a first terminal of the second switch SW2 and a first terminal of the first switch SW1 are respectively coupled to the second sensing terminal ISNSM and the first sensing terminal ISNSP, and a second terminal of the first switch SW1 is coupled to a second terminal of the third switch SW3 to form a second common node T2, which is coupled to the first terminal of the first drop element R1. The current sense circuit 400 has plural controllable switches (e.g., three controllable switches shown in FIG. 6), and by controlling the controllable switches, the current sense circuit 400 may be controlled to operate under a normal operation mode or a calibration mode, and the current sense circuit 400 may have a calibration function.

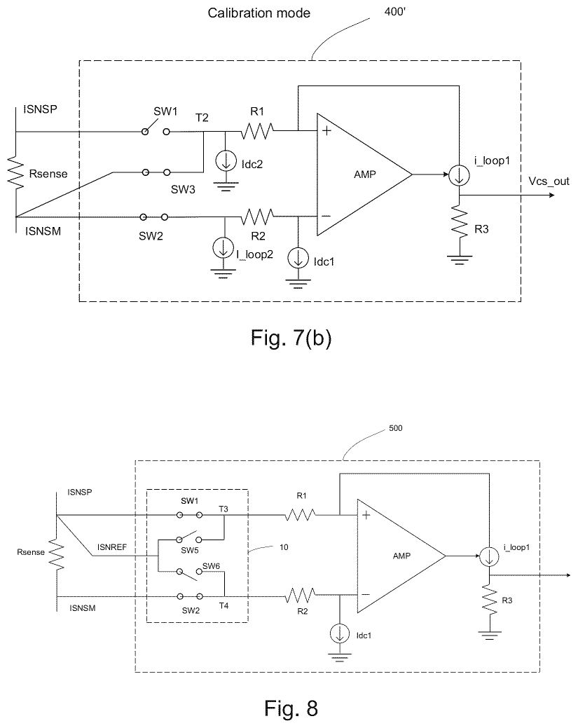

FIGS. 7(a) and 7(b) schematic shows the working principle of the calibration mode of a current sense circuit 400′ according to an embodiment of the present disclosure. In some embodiments, the current sense circuit 400′ in FIGS. 7(a) and 7(b) further also includes a fourth current source i_loop2 coupled in series with the second terminal of the second switch SW2 and a third current source Idc2 coupled in series with the second common node T2. The current value provided by the third current source Idc2 is the same as a current value provided by the current source Idc1, and a current value provided by the fourth current source i_loop2 is the same as a current value provided by the voltage-controlled current source i_loop1. For example, a current mirror is used for replicating the current source Idc1, and provide the copied current as the third current source Idc2. And, a current mirror is used for replicating the first current source i_loop1, and provide the copied current as the fourth current source i_loop2. By adding the third current source Idc2 and the fourth current source i_loop2, the influence of the parasitic resistance (e.g., due to metal wires) on the current sensing accuracy can be effectively reduced.

As shown in FIG. 7(a), under a normal operation mode, the first switch SW1 and the second switch SW2 are turned on, and the third switch SW3 is turned off. When the operating condition changes (e.g., the temperature changes) or when the user considers calibration is needed, control signals are provided to control the three switches to make the current sense circuit 400′ operate under the calibration mode. Under the calibration mode, as shown in FIG. 7(b), the second switch SW2 and the third switch SW3 are turned on, and the first switch SW1 is turned off. In other words, the two input terminals of the current sense circuit 400′ (e.g., the two input terminals of the operational amplifier AMP) are coupled to the same terminal (the second sensing terminal ISNSM) to receive the same voltage, and there is no current flowing across the two input terminals of the current sense circuit 400′ (i.e., zero current 0 A). Accordingly, under the calibration mode, the value of the output voltage Vcs_out (i.e., Vcs_out(0 A)) is obtained and recorded. In some embodiments, the value of the output voltage (i.e., Vcs_out(0 A)) is compared with a preset value to obtain the deviation. When the current sense circuit operates under a normal operation mode, the deviation is taken into consideration to compensate the output voltage.

FIG. 8 is a current sense circuit 500 according to one embodiment of the present disclosure. Compared with the current sense circuit 100 in FIG. 1, the current sense circuit 500 further includes a first switch SW1, a second switch SW2, a fifth switch SW5, and a sixth switch SW6. The first switch SW1 is coupled between the first sensing terminal ISNSP and the first drop element R1. The second switch is coupled between the second sensing terminal ISNSM and the second drop element R2. The fifth switch SW5 is coupled between a calibration input terminal ISNREF and the first drop element R1. The sixth switch SW6 is coupled between the calibration input terminal ISNREF and the second drop element R2. For example, the fifth switch SW5 has a first terminal coupled to a first terminal of the sixth switch SW6 to form a calibration input terminal ISNREF. While the first switch SW1 has a first terminal coupled to the first sensing terminal ISNSP, the first switch SW1 has a second terminal coupled to a second terminal of the fifth switch SW5 to form the third common node T3, which is coupled to the first terminal of the first drop element R1. While the second switch SW2 has a first terminal coupled to the second sensing terminal ISNSM, the second switch SW2 has a second terminal coupled to a second terminal of the sixth switch SW6 to form the fourth common node T4, which is coupled to the first terminal of the second drop element R2.

In FIG. 8, the calibration input terminal ISNREF is illustrated as being coupled to the first sensing terminal ISNSP, but it should not limit the scope of the present disclosure. In another embodiment, the calibration input terminal ISNREF is coupled to the second sensing terminal ISNSM. In some embodiments, the calibration input terminal ISNREF is not connected to any one of the first sensing terminal ISNSP and the second sensing terminal ISNSM.

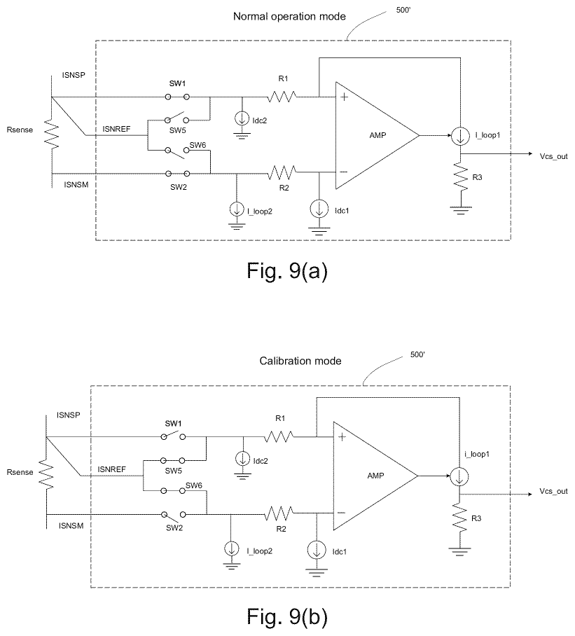

FIGS. 9(a) and 9(b) are schematic circuit diagrams showing the working principle of the calibration mode of a current sense circuit 500′ according to an embodiment of the present disclosure. In some embodiments, the current sense circuit 500 in FIGS. 9(a) and 9(b) further includes a third current source Idc2 coupled in series with the third common node T3 and a fourth current source I_loop2 coupled in series with between the fourth common node T4. The current value provided by the third current source Idc2 is the same as a current value provided by the current source Idc1, and a current value provided by the fourth current source i_loop2 is the same as a current value provided by the first current source i_loop1. For example, a current mirror is used for replicating the current source Idc1, and provide the copied current as the third current source Idc2. And, a current mirror is used for replicating the first current source i_loop1, and provide the copied current as the fourth current source i_loop2. By adding the third current source Idc2 and the fourth current source i_loop2, the influence of the parasitic resistance on the current sensing accuracy (e.g., due to metal wires) can be effectively reduced.

As shown in FIG. 9(a), under a normal operation mode, the first switch SW1 and the second switch SW2 are turned on, and the fifth switch SW5 and the sixth switch SW6 are turned off. When the operating condition changes (e.g., the temperature changes) or when the user considers calibration is needed, control signals are provided to control the three switches to make the current sense circuit 500′ operate under the calibration mode. Under the calibration mode, as shown in FIG. 9(b), the first switch SW1 and the second switch SW2 are turned off, and the fifth switch SW5 and the sixth switch SW6 are turned on. In other words, the two input terminals of the current sense circuit 500′ (e.g., the two input terminals of the operational amplifier AMP) are coupled to the same terminal (e.g., the first sensing terminal ISNSP or the second sensing terminal ISNSM) to receive the same voltage, and there is no current flowing across the two input terminals of the current sense circuit 500′ (i.e., zero current 0 A). Accordingly, under the calibration mode, the value of the output voltage Vcs_out (i.e., Vcs_out(0 A)) is obtained and recorded. In some embodiments, the value of the output voltage (i.e., Vcs_out(0 A)) is compared with a preset value to obtain the deviation. When the current sense circuit operates under a normal operation mode, the deviation is taken into consideration to compensate the output voltage.

Although the present invention has been described with reference to several exemplary embodiments, it is to be understood that the terms used are illustrative and exemplary rather than restrictive terms. Since the present invention can be embodied in various forms without departing from the spirit or substance of the invention, it should be understood that the above-described embodiments are not limited to any foregoing details, but are to be construed broadly within the spirit and scope defined by the appended claims. Therefore, all changes and modifications falling within the scope of the claims or their equivalents shall be covered by the appended claims.

What is claimed is:

1. A current sense circuit for sensing a current flowing through a device, comprising:
a first sensing terminal configured to be coupled to a first terminal of a current sense resistor coupled in series with the device;
a second sensing terminal configured to be coupled to a second terminal of the current sense resistor;
a sensing output terminal configured to provide a sensing signal indicative of the current flowing through the current sense resistor; and
a current source coupled to the second sensing terminal of the current sense circuit.

2. The current sense circuit of claim 1, further comprising:
an operational amplifier having a first input terminal, a second input terminal, and an output terminal, wherein a first terminal of the current source is coupled to the second input terminal of the operational amplifier, and a second terminal of the current source is coupled to a reference ground.

3. The current sense circuit of claim 2, further comprising:
a first drop element having a first terminal coupled to the first sensing terminal and a second terminal coupled to the first input terminal of the operational amplifier;
a second drop element having a first terminal coupled to the second sensing terminal and a second terminal coupled to the second input terminal of the operational amplifier; and
a first voltage-controlled current source having a first terminal coupled to the first input terminal of the operational amplifier, a second terminal coupled to the reference ground through a third drop element, and a control terminal coupled to the output terminal of the operational amplifier.

4. The current sense circuit of claim 3, further comprising:
a third current source coupled in series with the first drop element; and
a fourth current source coupled in series with the second drop element, wherein a current value provided by the third current source is the same as a current value provided by the current source, and a current value provided by the fourth current source is the same as a current value provided by the first voltage-controlled current source.

5. The current sense circuit of claim 1, wherein the current sense circuit has a calibration mode, and the current sense circuit is not connected to the current sense resistor when the current sense circuit is operated under the calibration mode.

6. The current sense circuit of claim 3, wherein the current sense circuit further comprises a plurality of switches, the switches are coupled to at least of the first drop element and the second drop element, and the switches are controlled to be turned on or off by control signals.

7. The current sense circuit of claim 6, wherein the current sense circuit comprises a normal operation mode, and a calibration mode.

8. The current sense circuit of claim 3, further comprising:
a first switch having a first terminal coupled to the first sensing terminal and a second terminal coupled to the first terminal of the first drop element;
a second switch having a first terminal coupled to the second sensing terminal; and
a third switch having a first terminal coupled to the first sensing terminal, wherein a second terminal of the second switch is coupled to a second terminal of the third switch to form a first common node, and the first common node is coupled to the first terminal of the second drop element.

9. The current sense circuit of claim 3, further comprising:
a first switch having a first terminal coupled to the first sensing terminal;
a second switch having a first terminal coupled to the second sensing terminal and a second terminal coupled to the first terminal of the second drop element; and
a third switch having a first terminal coupled to the second sensing terminal, wherein a second terminal of the first switch is coupled to a second terminal of the third switch to form a second common node, and the second common node is coupled to the first terminal of the first drop element.

10. The current sense circuit of claim 3, further comprising:
a first switch having a first terminal coupled to the first sensing terminal;
a second switch having a first terminal coupled to the second sensing terminal;
a fifth switch having a first terminal coupled to a calibration input terminal; and
a sixth switch having a first terminal coupled to the calibration input terminal, a second terminal of the first switch is coupled to a second terminal of the fifth switch to form a third common node, the third common node is coupled to the first terminal of the first drop element, a second terminal of the second switch is coupled to a second terminal of the sixth switch to form a fourth common node, wherein the fourth common node is coupled to the first terminal of the second drop element.

11. The current sense circuit of claim 10, wherein the calibration input terminal is coupled to the first sensing terminal or the second sensing terminal.

12. The current sense circuit of claim 10, wherein the calibration input terminal is not coupled to the first sensing terminal and not coupled to the second sensing terminal.

13. A current sense circuit for sensing a current flowing through a device, wherein the current sense circuit comprises:
a first sensing terminal coupled to a first terminal of a current sense resistor coupled in series with the device;
a second sensing terminal coupled to a second terminal of the current sense resistor;
a sensing output terminal configured to provide a voltage signal indicative of the current flowing through the current sense resistor, wherein:
when the voltage signal is equal to a first value, the current flowing through the current sense resistor is zero;
when the voltage signal is greater than the first value, the current flows in a first direction from the first terminal of the current sense resistor to the second terminal of the current sense resistor; and
when the voltage signal is less than the first value, the current flows a second direction from the second terminal of the current sense resistor to the first terminal of the current sense resistor.

14. The current sense circuit of claim 13, further comprising:
a current source coupled to the second terminal of the current sense resistor.

15. A power integrated circuit, comprising:
a current sense circuit configured to sense a current flowing through a device, wherein the current sense circuit is configured operate under a normal operation mode or a calibration mode, wherein:
under the normal operation mode, the current sense circuit is configured to sense the current flowing through the device and provide a voltage signal indicative of the current; and
under the calibration mode, the device is not connected to the current sense circuit.

16. The power integrated circuit of claim 15, wherein the current sense circuit further comprises:
a switch circuit coupled between a first sensing terminal and a second sensing terminal of the current sense circuit.

17. The power integrated circuit of claim 15, wherein the current sense circuit comprises:
a first sensing terminal configured to be coupled to a first terminal of a current sense resistor coupled in series with the device;
a second sensing terminal configured to be coupled to a second terminal of the current sense resistor;
a sensing output terminal configured to provide a sensing signal indicative of the current flowing through the current sense resistor; and
a current source coupled to the second sensing terminal of the current sense circuit.

18. The power integrated circuit of claim 17, wherein the current sense circuit further comprises:
an operational amplifier having a first input terminal, a second input terminal, and an output terminal, wherein a first terminal of the current source is coupled to the second input terminal of the operational amplifier, and a second terminal of the current source is coupled to a reference ground;
a first drop element having a first terminal coupled to the first sensing terminal and a second terminal coupled to the first input terminal of the operational amplifier;
a second drop element having a first terminal coupled to the second sensing terminal and a second terminal coupled to the second input terminal of the operational amplifier; and
a first voltage-controlled current source having a first terminal coupled to the first input terminal of the operational amplifier, a second terminal coupled to the reference ground through a third drop element, and a control terminal coupled to the output terminal of the operational amplifier.

19. The power integrated circuit of claim 18, wherein the current sense circuit further comprises:
a third current source coupled in series with the first drop element; and
a fourth current source coupled in series with the second drop element, wherein a current value provided by the third current source is the same as a current value provided by the current source, and a current value provided by the fourth current source is the same as a current value provided by the first voltage-controlled current source.

20. The power integrated circuit of claim 18, wherein the current sense circuit further comprises:
a first switch having a first terminal coupled to the first sensing terminal and a second terminal coupled to the first terminal of the first drop element;
a second switch having a first terminal coupled to the second sensing terminal and a second terminal coupled to the first terminal of the second drop element; and
a third switch coupled between the first sensing terminal and the first terminal of the second drop element or coupled between the second sensing terminal and the first terminal of the first drop element.

21. The power integrated circuit of claim 18, wherein the current sense circuit further comprises:
a first switch having a first terminal coupled to the first sensing terminal;
a second switch having a first terminal coupled to the second sensing terminal;
a fifth switch having a first terminal coupled to a calibration input terminal; and
a sixth switch having a first terminal coupled to the calibration input terminal, a second terminal of the first switch is coupled to a second terminal of the fifth switch to form a third common node, the third common node is coupled to the first terminal of the first drop element, a second terminal of the second switch is coupled to a second terminal of the sixth switch to form a fourth common node, wherein the fourth common node is coupled to the first terminal of the second drop element.
